(19) United States
(12) Patent Application Publication
(10) Pub. No.: US 2012/0153437 A1
(43) Pub. Date: Jun. 21, 2012

(54) ESD PROTECTION STRUCTURE FOR 3D IC

(75) Inventors: Kuan-Neng Chen, Hsinchu City (TW); Ming-Fang Lai, Chiayi County (TW); Hung-Ming Chen, Hsinchu County (TW)

(73) Assignee: NATIONAL CHIAO TUNG UNIVERSITY, Hsinchu City (TW)

(21) Appl. No.: 13/041,358

(22) Filed: Mar. 5, 2011

(30) Foreign Application Priority Data
Dec. 20, 2010 (TW) 99144817

(51) Int. Cl. H01L 29/06

(52) U.S. Cl. 257/546; 257/E29.019

(57) ABSTRACT

An electrostatic discharge (ESD) protection structure for a 3D IC is provided. The ESD protection structure includes a first active layer, a through-silicon via (TSV) device and a second active layer. The TSV is disposed in the first active layer, and the second active layer is stacked with the first active layer. The second active layer includes a substrate and an ESD protection device, wherein the ESD protection device having a doping area embedded in the substrate, and the ESD protection device electrically connects the TSV device.

### CROSS-REFERENCE TO RELATED APPLICATION

This application claims the priority benefit of Taiwan application serial no. 99144817, filed on Dec. 20, 2010. The entirety of the above-mentioned patent application is hereby incorporated by reference herein and made a part of this specification.

### BACKGROUND

1. Field of the Invention

The invention relates to an electrostatic discharge (ESD) protection structure. Particularly, the invention relates to an ESD protection structure for a three-dimensional (3D) integrated circuit (IC).

2. Description of Related Art

Along with complexity improvement of circuit designs and rapid development of semiconductor fabrication processes, and demand for circuit performance, integrated circuits (ICs) are developed to have a three-dimensional (3D) structure, so as to increase the circuit performance. Moreover, since different process techniques can be used in different layers of the 3D circuit, different processes can be used according to a circuit requirement, and then chips are stacked, so as to reduce fabrication cost.

Interconnections of various chips are implemented through through-silicon vias (TSVs), and the TSVs are fabricated between chips or wafers for vertical connections, which is a new technique to achieve interconnections of the chips in the current 3D IC fabrication technique. Different to a conventional IC package bonding technique and a stacking technique of using bumps, by using the TSVs, a maximum stacking density of the chips in the 3D structure and a minimum size thereof are achieved, and a device speed is improved, and a signal delay and power consumption are reduced, so that it is one of the most important techniques of the 3D IC.

However, since the 3D IC are formed by a plurality of layers of chips, and process techniques and supply voltages on different chips are probably different, and a TSV device is used to connect different chips, various high-voltage static electricity or noises may pass through the TSV device, for example, the static electricity of a human-body model (HBM), a machine model (MM), a charged-device model (CDM) or a field-induced model. (FIM) can be transmitted to the stacked chips through the TSV, which may cause a damage of the 3D IC or the TSV device.

In the conventional 3D IC, by disposing an electrostatic discharge (ESD) protection device next to the TSV to connect the TSV, the static electricity in the TSV can be discharged to external of the IC through the ESD protection device. Although such method may protect the 3D IC, fabrication steps of the 3D IC are increased, so that fabrication of the 3D IC is more complicated, and a production cost thereof is increased.

### SUMMARY OF THE INVENTION

The invention is directed to an electrostatic discharge (ESD) protection structure for a three-dimensional (3D) integrated circuit (IC), which can effectively achieve ESD protection, and meanwhile reduce fabrication cost of the IC.

The invention provides an ESD (electrostatic discharge) protection structure for a 3D IC. The ESD protection structure includes a first active layer, a through-silicon via (TSV) device and a second active layer. The TSV device is disposed in the first active layer, and the second active layer is stacked with the first active layer. The second active layer includes a substrate and an ESD protection device, wherein the ESD protection device has a doping area embedded in the substrate, and the ESD protection device is electrically connected to the TSV device.

In an embodiment of the invention, the substrate is a P-type substrate, and the doping area is an N-type doping area.

In an embodiment of the invention, the second active layer further includes a well embedded between the substrate and the ESD protection device.

In an embodiment of the invention, the substrate is a P-type substrate, the well is an N-type well, and the doping area is a P-type doping area.

In an embodiment of the invention, the second active layer further includes a wire layer and a first metal contact layer. The first metal contact layer is located on an upper surface of the second active layer, and the ESD protection device is electrically connected to a first end of the TSV device through the wire layer and the first metal contact layer.

In an embodiment of the invention, the first active layer further includes a second metal contact layer located on a first surface of the first active layer, and the first end of the TSV device is electrically connected to the first metal contact layer through the second metal contact layer.

In an embodiment of the invention, the first active layer further includes a third metal contact layer located on a second surface of the first active layer, and a second end of the TSV device is electrically connected to ground through the first metal contact layer.

In an embodiment of the invention, the first active layer is a first wafer or a first die.

In an embodiment of the invention, the second active layer is a second wafer or a second die.

According to the above descriptions, in the invention, an ESD protection device is disposed next to the active device to achieve the ESD protection effect, where a conducting voltage of the ESD protection device is smaller than a breakdown voltage of the active device. Moreover, the ESD protection device is disposed in the active layer which is in a different layer with that of the TSV device, so as to avoid increasing additional fabrication steps and save a production cost of the 3D IC.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an electrostatic discharge (ESD) protection structure for a three-dimensional (3D) integrated circuit (IC) according to an embodiment of the invention.

FIG. 2 is a schematic diagram of an ESD protection structure for a 3D IC according to another embodiment of the invention.

FIG. 3 is a schematic diagram of an ESD protection structure for a 3D IC according to another embodiment of the invention.

FIG. 4 is a schematic diagram of an ESD protection structure for a 3D IC according to another embodiment of the invention.

FIG. 5 is a schematic diagram of an ESD protection structure for a 3D IC according to another embodiment of the invention.

### DETAILED DESCRIPTION OF DISCLOSED EMBODIMENTS

A concept of the invention is to combine a through-silicon via (TSV) device and an electrostatic discharge (ESD) protection device of a three-dimensional (3D) integrated circuit (IC) to protect the 3D IC and the TSV device from being damaged by the electrostatic discharge.

A plurality of embodiments is provided below to describe applications of the invention, though the invention may, however, be embodied in many different forms and should not be construed as being limited to the embodiments set forth herein; rather, these embodiments are provided so that this disclosure will be thorough and complete, and will fully convey the concept of the invention to those skilled in the art. In the accompanying drawings, sizes of different layers and regions and relative sizes are probably exaggerated for clarity. For simplicity's sake, only a structure of the invention is illustrated in each of the drawings, and other circuit components on the substrate are not illustrated, though those skilled in the art should understand that components suitable for the 3D IC can all be disposed on the substrate according to an actual requirement.

Terms used herein are only used to describe the specific embodiments, which are not used to limit the invention. For example, unless limited otherwise, the term “one” or “the” of the single form may also represent the plural form. The terms such as “first” and “second” are used for describing various devices, areas and layers, etc., though such terms are only used for distinguishing one device, one area or one layer from another device, another area or another layer. Therefore, the first area can also be referred to as the second area without departing from the spirit of the invention, and the others are deduced by analogy.

Moreover, space orientation terms such as “under”, “on” “up” “down”, etc. are used to describe a relationship between a device or a characteristic and another device or another characteristic in the drawing. It should be noticed that the space orientation term can cover different orientations of the device besides the orientation of the device illustrated in the drawing. For example, if the device in the drawing is turned over, the device located “under” or “below” the other devices or characteristics is reoriented to be located “above” the other devices or characteristics. Therefore, the space orientation term “under” may include two orientations of “above” and “below”.

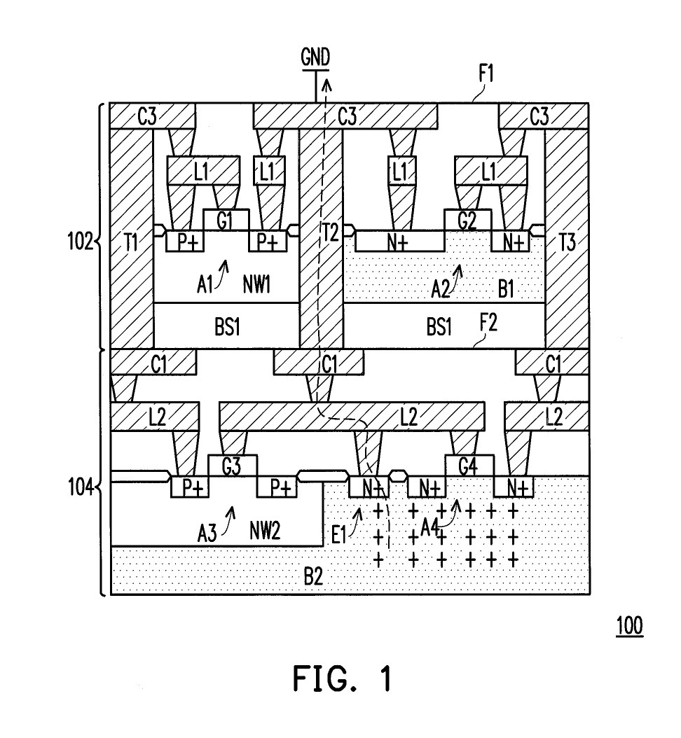

FIG. 1 is a schematic diagram of an ESD protection structure for a 3D IC according to an embodiment of the invention. Referring to FIG. 1, the 3D IC 100 includes a first active layer 102 and a second active layer 104. The first active layer 102 and the second active layer 104 can be respectively a wafer and/or a die (i.e. the first active layer 102 and the second active layer 104 can be simultaneously wafers or dies, or one of the first active layer 102 and the second active layer 104 is a wafer and another one of the first active layer 102 and the second active layer 104 is a die, and vice versa).

The first active layer 102 has a first surface F1 and a second surface F2, and includes active devices A1 and A2, a base BS1 and a plurality of through silicon via (TSV) devices T1, T2 and T3, where the base BS1 is, for example, an oxide layer or a semiconductor on insulator (SOI), which is located on the first surface F1 of the first active layer 102. A second end of each TSV device passes through a third metal contact layer C3 on the second surface F2 of the first active layer 102 and is electrically connected to the ground GND, and a first end of each TSV device passes through the first surface F1 of the first active layer 102.

The active devices A1 and A2 are located on the base BS1 and are respectively located between the TSV devices T1 and T2 and the TSV devices T2 and T3. The active devices A1 and A2 are electrically connected to the third metal contact layer C3 through a wire layer L1. In the present embodiment, the active device A1 is a P-type metal oxide semiconductor (PMOS) transistor, which is formed by an N-type well NW1 and a gate G1, a source and a drain (i.e. P-type doping areas (P+) located at two sides of the gate G1) in the N-type well NW1, where the gate G1, the source and the drain of the active device A1 are electrically connected to the third metal contact layer C3 through the wire layer L1.

Moreover, in the present embodiment, the active device A2 is a N-type metal oxide semiconductor (NMOS) transistor, which is formed by a P-type substrate B1 and a gate G2, a source and a drain (i.e. N-type doping areas (N+) located at two sides of the gate G2) in the P-type substrate B1, where the gate G2, the source and the drain of the active device A2 are electrically connected to the third metal contact layer C3 through the wire layer L1. A material of the wire layer L1 is, for example, aluminium or copper.

The second active layer 104 includes a P-type substrate B2, active devices A3 and A4 and at least an ESD protection device E1 located on the P-type substrate B2. In the present embodiment, the active device A3 is a PMOS transistor, which is formed by a N-type well NW2 and a gate G3, a source and a drain (i.e. P-type doping areas (P+) at two sides of the gate G3) in the N-type well NW2. The active device A4 is an NMOS transistor, which is formed by a P-type substrate B2 and a gate G4, a source and a drain (i.e. N-type doping areas (N+) located at two sides of the gate G4) in the P-type substrate B2. Moreover, the ESD protection device E1 is an N-type doping area (N+), which is located between the active device A3 and the active device A4.

The gate G3 of the active device A3, the gate G4 of the active device A4 and the ESD protection device E1 (which is an N-type doping area (N+) in the present embodiment) are connected to each other through a wire layer L2, and the wire layer L2 is electrically connected to a first end of the TSV device T2 through a first metal contact layer C1 on an upper surface of the second active layer 104. A material of the wire layer L2 is, for example, aluminium or copper. One of the two P-type doping areas (P+) of the active device A3 is electrically connected to the TSV device T1 through the wire layer L2 and the first metal contact layer C1, and one of the two N-type doping areas (N+) of the active device A4 is electrically connected to the TSV device T3 through the wire layer L2 and the first metal contact layer C1.

Since a conducting voltage of a diode formed by the ESD protection device E1 and the P-type substrate B2 is smaller than a breakdown voltage of the gate G3 of the active device A3 or the gate G4 of the active device A4, when the wafer (or die) carries the electrostatic charges (for example, electrostatic positive charges carried by the P-type substrate B2 in the present embodiment) due to friction or other reasons, the electrostatic charges can be discharged to the ground GND through an electrostatic discharge (ESD) current path formed by the ESD protection device E1, the wire layer L2, the first metal contact layer C1, the TSV device T2 and the third metal contact layer C3, so as to prevent the electrostatic charges in the P-type substrate B2 from breaking through the gate G3 of the active device A3 or the gate G4 of the active device A4 to damage the active device A3 or A4.

It should be noticed that during a high-class semiconductor fabrication process, the gate breakdown voltage of the active device A3 or A4 is probably smaller than the conducting voltage of the diode formed by the ESD protection device E1 and the P-type substrate B2, so that a doping concentration of the ESD protection device E1 is required to be increased. In this way, the conducting voltage of the ESD protection device E1 is smaller than the gate breakdown voltage of the active device A3 or the active device A4, so as to achieve the ESD protection effect. Moreover, the charges carried by the P-type substrate B2 can also be electrostatic negative charges, and in this case, the electrostatic negative charges can also be discharged to external through the aforementioned ESD current path, so as to avoid damaging the active device A3 or A4.

According to the above descriptions, by disposing the ESD protection device E1 with a conducting voltage smaller than the breakdown voltage of the active device next to the active devices A3 and A4, the electrostatic charges in the 3D IC 100 can be guided to the ESD current path with a relatively low threshold voltage, so as to avoid damaging the active device A3 or A4. By disposing the ESD protection device at the active layer which is in a different layer with that of the TSV devices, increasing of additional fabrication steps is avoided. Namely, by disposing the ESD protection device E1 next to the active devices A3 and A4, only a mask pattern is required to be modified during the fabrication process without increasing the number of the masks as that does of the conventional technique for fabricating the ESD protection device next to the TSV device. Therefore, according to the ESD protection structure of the 3D IC disclosed by the present embodiment, the production cost of the 3D IC can be greatly reduced.

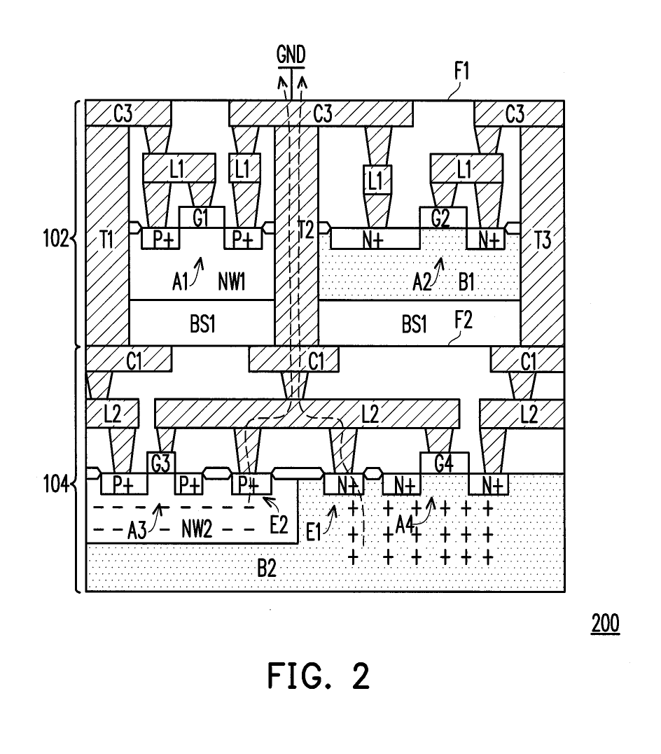

It should be noticed that the number and patterns of the active devices in the above embodiment are only used as an exemplary embodiment, and the invention is not limited thereto. Moreover, when the static electricity is generated on the wafer (or die), the electrostatic charges are not limited to only exist in the P-type substrate B2, which can also exist in the N-type well NW2 of the active device A3. In order to prevent the electrostatic charges in the N-type well NW2 of the active device A3 from damaging the device, another ESD protection device can be disposed in the N-type well NW2 to remove the electrostatic charges in the N-type well NW2. FIG. 2 is a schematic diagram of an ESD protection structure for a 3D IC according to another embodiment of the invention. Referring to FIG. 2, a difference between the 3D IC 200 of the present embodiment and the 3D IC 100 of the embodiment of FIG. 1 is that the N-type well NW2 of the 3D IC 200 further includes an ESD protection device E2 located next to the active device A3.

In the present embodiment, the ESD protection device E2 is a P-type doping area (P+), which is electrically connected to the TSV device T1 in the first active layer 102 through the wire layer L2 and the first metal contact layer C1, where a conducting voltage of a diode formed by the ESD protection device E2 and the N-type well NW2 is smaller than the breakdown voltage of the active device A3, so that when the electrostatic charges (for example, electrostatic negative charges) are generated in the N-type well NW2, the electrostatic charges can be guided to the ground GND through an ESD current path formed by the ESD protection device E2, the wire layer L2, the first metal contact layer C1, the TSV device T2 and the third metal contact layer C3, so as to prevent the electrostatic charges in the N-type well NW2 from breaking through the gate G3 of the active device A3 or the gate G4 of the active device A4 to damage the active device A3 or A4. It should be noticed that the charges carried by the N-type well NW2 can also be electrostatic positive charges, and in this case, the electrostatic positive charges can also be discharged to external through the aforementioned ESD current path, so as to avoid damaging the active device A3 or A4.

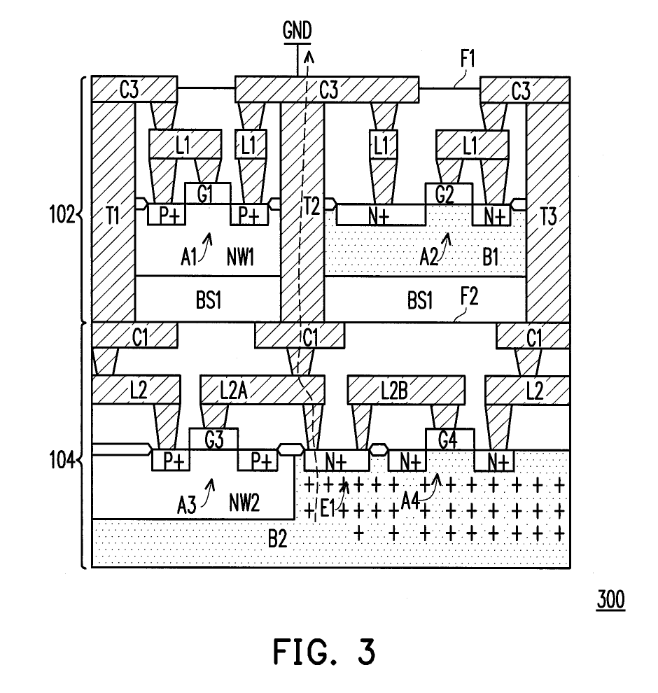

FIG. 3 is a schematic diagram of an ESD protection structure for a 3D IC according to another embodiment of the invention. Referring to FIG. 2, a difference between the 3D IC 300 of the present embodiment and the 3D IC 100 of the embodiment of FIG. 1 is that in the 3D IC 300, the wire layer L2 originally coupled to the ESD protection device E1, the first metal contact layer C1, the gate G3 of the active device A3 and the gate G4 of the active device A4 is now divided into wire layers L2A and L2B. Namely, the gate G4 of the active device A4 cannot be electrically connected to the TSV device T2 directly through the wire layer L2 and the first metal contact layer C1 as that shown in FIG. 2, but has to electrically connect the TSV device T2 through the wire layer L2B, the ESD protection device E1, the wire layer L2A and the first metal contact layer C1.

Therefore, the electrostatic charges in the P-type substrate B2 are discharged to the ground GND through a current path with a relatively small impedance (i.e. flow to the ground GND through the N-type doping area (N+) of the ESD protection device E1, the wire layer L2A, the first metal contact layer C1, the TSV device T2 and the third metal contact layer C3) other than a current path flowing through the gate G4 of the active device A4, so that the gate G4 of the active device A4 is protected from being damaged.

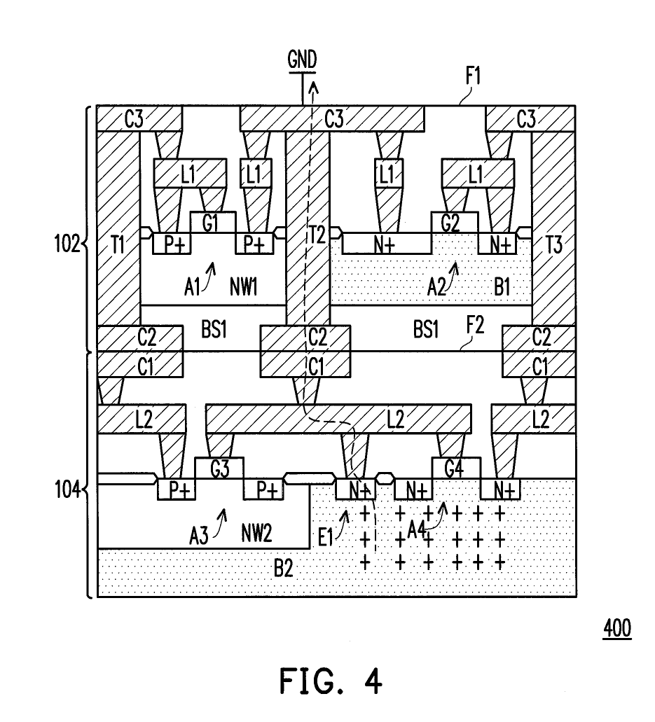

In the above embodiment, the first ends of the TSV devices T1, T2 and T3 in the first active layer 102 pass through the first surface F1 of the first active layer 102 and are directly connected to the first metal contact layer C1. However, in some embodiments, the first ends of the TSV devices T1, T2 and T3 can be first connected to another metal contact layer and then electrically connected to the first metal contact layer C1. FIG. 4 is a schematic diagram of an ESD protection structure for a 3D IC 400 according to another embodiment of the invention. In FIG. 4, the second surface F2 of the first active layer 102 further includes a second metal contact layer C2, which is connected to the first ends of the TSV devices T1, T2 and T3, and is electrically connected to the first metal contact layer C1 of the second active layer 104. Similarly, the 3D IC 400 of the present embodiment can use the same method as that of the 3D IC 100 of FIG. 1 to get rid of the electrostatic charges in the second active layer 104, though a difference there between is that an ESD current path of the 3D IC 400 of the present embodiment further includes the second metal contact layer C2 compared to the ESD current path of the 3D IC 100, and those skilled in the art can deduce an operation principle of the 3D IC 400 according to the aforementioned embodiments, so that detailed descriptions thereof are not repeated.

Moreover, in the embodiment of FIG. 1, the first active layer 102 and the second active layer 104 are stacked through a face-to-back stacking process to form the 3D IC 100, though the invention is not limited thereto. In other words, in the present embodiment, the two active layers can also be stacked through a face-to-face stacking process to form the 3D IC.

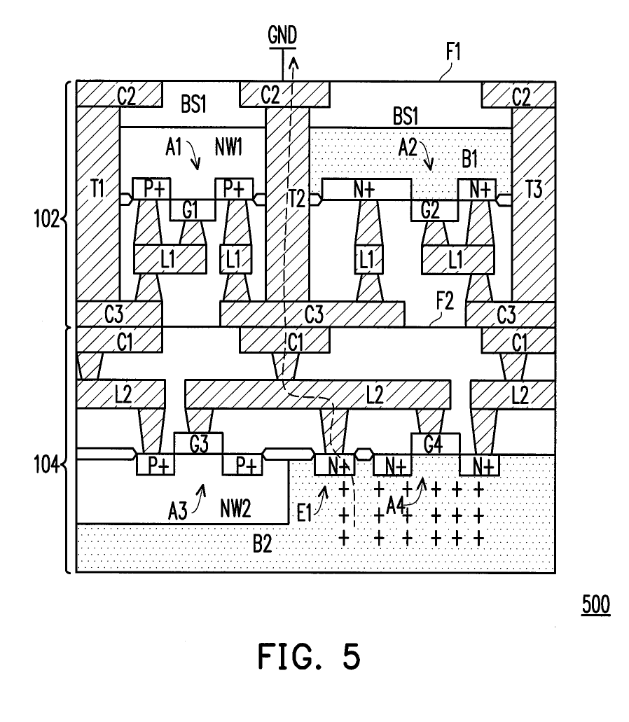

In detail, FIG. 5 is a schematic diagram of a 3D IC according to another embodiment of the invention. Referring to FIG. 4 and FIG. 5, devices similar to that of the 3D IC 400 have similar referential numbers in FIG. 5, so that detailed descriptions thereof are not repeated. A difference between the 3D IC 500 of the present embodiment and the 3D IC 400 of FIG. 4 is that the first active layer 102 and the second active layer 104 in the 3D IC 400 are stacked through the face-to-back stacking process, though the first active layer 102 and the second active layer 104 in the 3D IC 500 are stacked through the face-to-face stacking process. Therefore, an ESD current path of the 3D IC 500 is that same to the ESD current path of the 3D IC 400, and though skilled in the art can deduce an operation principle of the 3D IC 500 according to the aforementioned embodiments, so that detailed descriptions thereof are not repeated.

Moreover, the ESD protection devices E1 and E2 are not limited to be implemented in the P-type substrate B2 and the N-type well NW2, and the ESD protection device E1 can also be implemented on an N-type substrate as long as the N-type doped ESD protection device E1 is changed to the P-type doped ESD protection device E1. Moreover, the ESD protection device E2 can also be implemented in a P-type well as long as the P-type doped ESD protection device E2 is changed to a N-type doped ESD protection device E2.

In summary, in the invention, an ESD protection device is disposed next to the active device to achieve the ESD protection effect, where a conducting voltage of the ESD protection device is smaller than a breakdown voltage of the active device. Moreover, by disposing the ESD protection device in the active layer which is in a different layer with that of the TSV device, the ESD protection device and the active device are in the same active layer, so that during the fabrication process, the ESD protection device can be fabricated according to the original fabrication steps by only modifying the mask pattern without increasing additional fabrication steps, so that production cost of the 3D IC is saved.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electrostatic discharge (ESD) protection structure for a three-dimensional (3D) integrated circuit (IC) comprising:
a first active layer;
a through-silicon via (TSV) device, disposed in the first active layer, and
a second active layer, stacked with the first active layer, and the second active layer comprising:
a substrate; and
an ESD protection device, having a doping area embedded in the substrate, wherein the ESD protection device is electrically connected to the TSV device.

2. The ESD protection structure as claimed in claim 1, wherein the substrate is a P-type substrate, and the doping area is an N-type doping area.

3. The ESD protection structure as claimed in claim 1, wherein the second active layer further comprises:
a well, embedded between the substrate and the ESD protection device.

4. The ESD protection structure as claimed in claim 3, wherein the substrate is a P-type substrate, the well is an N-type well, and the doping area is a P-type doping area.

5. The ESD protection structure as claimed in claim 1, wherein the second active layer further comprises:
a wire layer; and
a first metal contact layer, located on an upper surface of the second active layer, wherein the ESD protection device is electrically connected to a first end of the TSV device through the wire layer and the first metal contact layer.

6. The ESD protection structure as claimed in claim 5, wherein the first active layer further comprises:
a second metal contact layer, located on a first surface of the first active layer, wherein the first end of the TSV device is electrically connected to the first metal contact layer through the second metal contact layer.

7. The ESD protection structure as claimed in claim 6, wherein the first active layer further comprises:
a third metal contact layer, located on a second surface of the first active layer, wherein a second end of the TSV device is electrically connected to ground through the first metal contact layer.

8. The ESD protection structure as claimed in claim 1, wherein the first active layer is a first wafer or a first die.

9. The ESD protection structure as claimed in claim 8, wherein the second active layer is a second wafer or a second die.
